(19) United States
(12) Patent Application Publication
(10) Pub. No.: US 2007/0148559 A1
(43) Pub. Date: Jun. 28, 2007

(54) Phase shift mask and method for fabricating the same

(75) Inventor: Myoung-Sul Yoo, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/478,180

(22) Filed: Jun. 28, 2006

(30) Foreign Application Priority Data
Dec. 27, 2005 (KR) 2005-0130470

(51) Int. Cl. G21K 5/00; G03F 1/00

(52) U.S. Cl. 430/5; 378/35

(57) ABSTRACT

A phase shift mask and a method for fabricating the same are provided. The phase shift mask includes: a substrate; a multiple thin layer structure formed over the substrate, the multiple thin layer structure including an opening formed to a predetermined depth; and an absorption material filling a portion of the opening. The method includes: preparing a substrate; forming a multiple thin layer structure over the substrate; etching a portion of the multiple thin layer structure to form an opening; and filling a portion of the opening with an absorption material.

### FIELD OF THE INVENTION

The present invention relates to a method for fabricating a semiconductor device; and more particularly, to a phase shift mask used in a lithography process for extreme ultraviolet (EUV) light and a method for fabricating the same.

### DESCRIPTION OF RELATED ARTS

In general, photolithography utilizes transmission optics, and particularly, a phase shift mask is used to improve resolution. The phase shift mask is formed in a structure including a phase shift layer, which can make a 180-degree phase shift of light impinging on a specific area of a quartz substrate. When a photolithography process is performed using the above phase shift mask, a phase difference between light transmitted through the phase shift layer and non-transmitted light is created. Thus, destructive interference takes place between the two lights, thereby improving resolution.

FIG. 1 is a simplified cross-sectional view illustrating a typical phase shift mask structure of a semiconductor device.

As illustrated, a multiple thin layer structure 4 is formed on a substrate 1, and an absorption material 5 is formed on a predetermined region of the multiple thin layer structure 4. The substrate 1 is formed of a material with low thermal expansion, and the multiple thin layer structure 4 is generally formed by depositing a molybdenum (Mo) layer 2 and a silicon (Si) layer 3 alternately and repeatedly. Each of the Mo layer 2 and the Si layer 3 is deposited to a thickness of 2 nm to 4 nm, and the total number of the repeatedly deposited Mo and Si layers 2 and 3 is 14.

The absorption material 5 is formed to a thickness of 80 nm to 150 nm. The absorption material 5 is necessary to obtain an aerial image and should provide a sufficient level of absorption to achieve high image contrast. However, since the phase shift mask is developed to be used in a photolithography process using transmission optics, it may be difficult to use the phase shift mask in a photolithography process for EUV light using reflective optics.

### SUMMARY OF THE INVENTION

It is, therefore, an object of the present invention to provide a phase shift mask of a semiconductor device, wherein the phase shift mask is capable of realizing micronized patterns by improving resolution through correcting a phase of a mask used in a lithography process for EUV light, and a method for fabricating the same.

In accordance with an aspect of the present invention, there is provided a phase shift mask of a semiconductor device, including: a substrate; a multiple thin layer structure formed over the substrate, the multiple thin layer structure including an opening formed to a predetermined depth; and an absorption material filling a portion of the opening.

In accordance with another aspect of the present invention, there is provided a method for fabricating a phase shift mask of a semiconductor device, including: preparing a substrate; forming a multiple thin layer structure over the substrate; etching a portion of the multiple thin layer structure to form an opening; and filling a portion of the opening with an absorption material.

### BRIEF DESCRIPTION OF THE DRAWINGS

The above text and features of the present invention will become better understood with respect to the following description of the embodiments given in conjunction with the accompanying drawings, in which:

FIG. 1 is a simplified cross-sectional view illustrating a typical phase shift mask structure of a semiconductor device;

FIG. 2 is a simplified cross-sectional view illustrating a phase shift mask structure of a semiconductor device in accordance with an embodiment of the present invention; and

FIG. 3 is a simplified cross-sectional view illustrating a method for fabricating a phase shift mask of a semiconductor device in accordance with an embodiment of the present invention; and

FIGS. 4A to 4C are diagrams illustrating the concept of photolithography using a phase shift mask in accordance with an embodiment of the present invention.

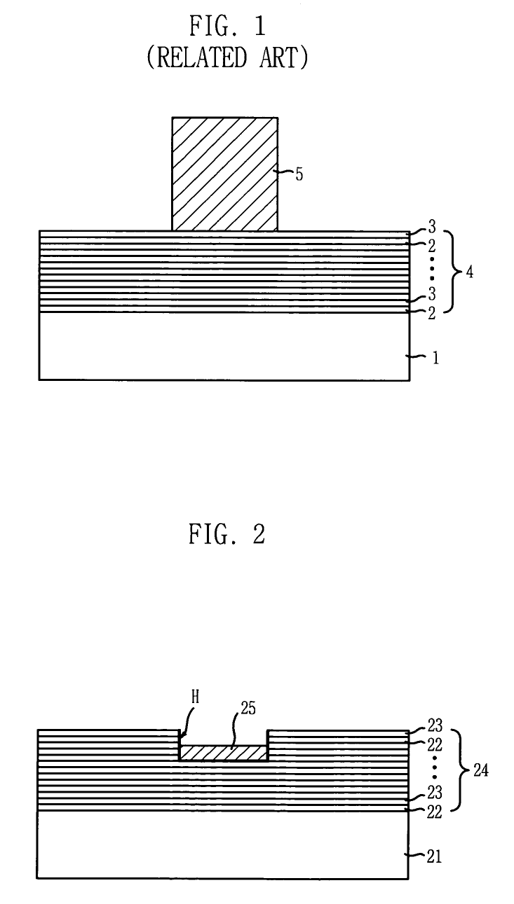

### DETAILED DESCRIPTION OF THE INVENTION

Hereinafter, exemplary embodiments of the present invention will be described in detail with reference to the accompanying drawings.

FIG. 2 is a simplified cross-sectional view illustrating a phase shift mask structure of a semiconductor device in accordance with an embodiment of the present invention.

As illustrated, a multiple thin layer structure 24 is formed over a substrate 21. The multiple thin layer structure 24 includes a molybdenum (Mo) layer 22 and a silicon (Si) layer 23, which are alternately and repeatedly stacked over each other in sequential order. The single Mo layer 22 has a thickness of approximately 2.8 nm, and the single Si layer 23 has a thickness of approximately 4.2 nm. In addition to the above mentioned layer structure of Mo/Si, other multiple thin layer structures can be used. For instance, the other multiple thin layer structure may include Mo/beryllium (Be), molybdenum ruthenium (MoRu)/Be or Ru/Be.

A predetermined portion of the multiple thin layer structure 24 is etched to form an opening H for forming a phase shift layer. An absorption material 25 is formed to a thickness filling a portion of the opening H. The absorption material 25 includes one selected from the group consisting of aluminum (Al), tantalum silicide (TaSi), titanium nitride (TiN), titanium (Ti), tungsten (W), chromium (Cr), nickel silicide (NiSi), and tantalum silicon nitride (TaSiN).

When a photolithography process is performed using the phase shift mask having the above resulting structure, destructive interference takes place between 180-degree-phase shifted light through the absorption material 25 and light with no phase shift at the boundary region. As a result, a decrease of contrast can be reduced, thereby improving contrast of an aerial image transmitted to a wafer.

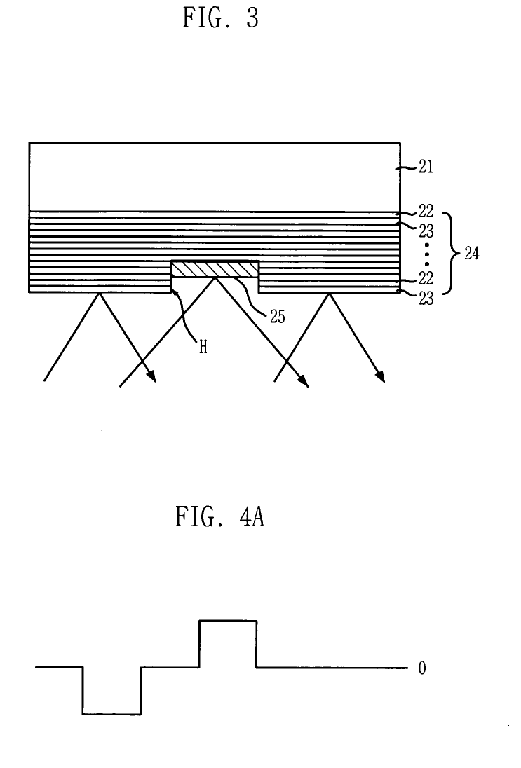

FIG. 3 is a simplified cross-sectional view illustrating a method for fabricating a phase shift mask in accordance with an embodiment of the present invention. Herein, the same reference numerals denote the same elements described in FIG. 2.

As illustrated, a multiple thin layer structure 24 is formed over a substrate 21. The multiple thin layer structure 24 includes a molybdenum (Mo) layer 22 and a silicon (Si) layer 23, which are alternately and repeatedly stacked over each other in sequential order. The single Mo layer 22 has a thickness of approximately 2.8 nm, and the single Si layer 23 has a thickness of approximately 4.2 nm. In addition to the above mentioned layer structure of Mo/Si, other multiple thin layer structures can be used. For instance, the other multiple thin layer structure may include Mo/Be, MoRu/Be or Ru/Be, wherein the number of the alternatively stacked layers 22 and 23 ranges from approximately 35 to approximately 45.

A predetermined portion of the multiple thin layer structure 24 is selectively etched to form an opening H where a phase shift layer is to be formed. In more detail of the formation of the opening H, a photoresist pattern is formed over a certain region of the multiple thin layer structure 24, and the predetermined portion of the multiple thin layer structure 24 is etched using the photoresist pattern as an etch mask. The opening H is formed by selectively etching the multiple thin layer structure 24 depending on the purpose of forming the opening H.

An absorption material 25 is formed to fill a portion of the opening H. The absorption material 25 includes one selected from the group consisting of Al, TaSi, TiN, Ti, W, Cr, NiSi, and TaSiN. The thickness of the absorption material 25 can be variable depending on the purpose of forming the absorption material 25.

When a photolithography process is performed using the phase shift mask having the above resulting structure, light is reflected through the multiple thin layer structure 24 and the absorption material 25. Particularly, light reflected from the multiple thin layer structure 24 and light reflected from the absorption material 25 have different phases, and thus, the resolution can be improved. More specifically, destructive interference takes place between 180-degree-phase shifted light and light with no phase shift at the boundary region between the multiple thin layer structure 24 and the absorption material 25. As a result, a decrease of contrast can be reduced. Hence, the contrast of an aerial image transmitted to a wafer can be increased.

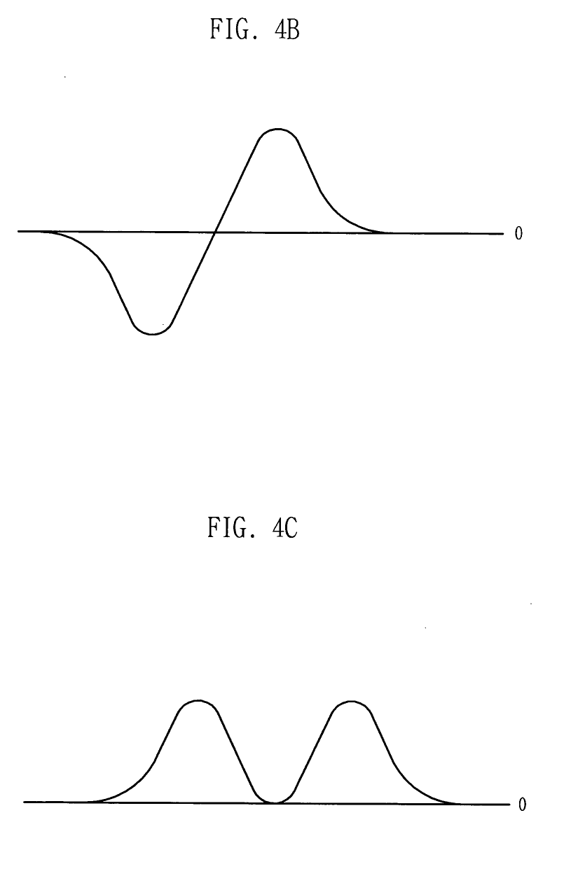

FIGS. 4A to 4C are diagrams illustrating the concept of photolithography for forming a phase shift mask in accordance with an embodiment of the present invention.

FIG. 4A is a diagram illustrating an energy level of light over a phase shift mask. FIG. 4B is a diagram illustrating an energy level of light over a wafer. FIG. 4C is a diagram illustrating a mechanism of improving the contrast by which a phase of light reflected from a reflection layer of a phase shift layer is inverted to thereby have destructive interference with light reflected from a region where the phase shift layer is not formed.

According to the exemplary embodiments of the present invention, the absorption material is buried in the multiple thin layer structure instead of being formed thereon. This burial of the absorption material results in a phase difference between light reflected from the multiple thin layer structure and light reflected from the absorption material. The phase difference can contribute to an improvement in the resolution. Also, the phase shift mask can be applied to an EUV photolithography process using reflective optics.

Since the typically used substrate, multiple thin layer structure and the absorption material can still be used in the above described embodiments of the present invention, the design of an EUV photolithography apparatus needs not to be modified and yet the resolution can be improved. As compared with the typically employed phase shift mask, the phase shift mask according to the exemplary embodiments of the present invention can be used as a mask for EUV photolithography. Thus, a process margin can also be improved. This improvement allows the formation of micronized patterns.

The present application contains subject matter related to the Korean patent application No. KR 2005-0130470, filed in the Korean Patent Office on Dec. 27, 2005, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A phase shift mask of a semiconductor device, comprising:
a substrate;
a multiple thin layer structure formed over the substrate, the multiple thin layer structure including an opening formed to a predetermined depth; and
an absorption material filling a portion of the opening.

2. The phase shift mask of claim 1, wherein the multiple thin layer structure includes multiple upper and lower layers alternately stacked over each other.

3. The phase shift mask of claim 2, wherein the multiple thin layer structure includes one selected from the group consisting of molybdenum (Mo)/silicon (Si), Mo/beryllium (Be), molybdenum ruthenium (MoRu)/beryllium (Be), and Ru/Be.

4. The phase shift mask of claim 3, wherein the lower layer of the multiple thin layer structure has a thickness of approximately 2.8 nm, and the upper layer of the multiple thin layer structure has a thickness of approximately 4.2 nm.

5. The phase shift mask of claim 3, wherein the number of the alternatively stacked upper and lower layers ranges from approximately 35 to approximately 45.

6. The phase shift mask of claim 1, wherein the absorption material includes one selected from the group consisting of aluminum (Al), tantalum silicide (TaSi), titanium (Ti), titanium nitride (TiN), tungsten (W), chromium (Cr), nickel silicide (NiSi), and tantalum silicon nitride (TaSiN).

7. A method for fabricating a phase shift mask of a semiconductor device, comprising:
preparing a substrate;
forming a multiple thin layer structure over the substrate;
etching a portion of the multiple thin layer structure to form an opening; and
filling a portion of the opening with an absorption material.

8. The method of claim 7, wherein the forming of the multiple thin layer structure comprises alternately stacking multiple lower layers and multiple upper layers over each other.

9. The method of claim 7, wherein the multiple thin layer structure includes one selected from the group consisting of molybdenum (Mo)/silicon (Si), Mo/beryllium (Be), molybdenum ruthenium (MoRu)/beryllium (Be), and Ru/Be.

10. The method of claim 9, wherein the lower layer of the multiple thin layer structure has a thickness of approximately 2.8 nm, and the upper layer of the multiple thin layer structure has a thickness of approximately 4.2 nm.

11. The method of claim 9, wherein the number of the alternately stacked upper and lower layers ranges from approximately 35 to approximately 45.

12. The method of claim 7, wherein the absorption material includes one selected from the group consisting of aluminum (Al), tantalum silicide (TaSi), titanium (Ti), titanium nitride (TiN), tungsten (W), chromium (Cr), nickel silicide (NiSi), and tantalum silicon nitride (TaSiN).
